(19) United States
(12) Patent Application Publication
(10) Pub. No.: US 2004/0005016 A1
(43) Pub. Date: Jan. 8, 2004

(54) High bit rate ultra-wideband OFDM

(76) Inventors: Ahmed Tewfik, Edina, MN (US); Ebrahim Saberinia, St. Paul, MN (US)

Correspondence Address: SCHWEGMAN, LUNDBERG, WOESSNER & KLUTH, P.A., P.O. BOX 2938, MINNEAPOLIS, MN, 55402, US

(21) Appl. No.: 10/191,769

(22) Filed: Jul. 8, 2002

(51) Int. Cl. H03C 3/00; H03K 7/06

(52) U.S. Cl. 375/302

(57) ABSTRACT

High-bit rate communication system for short range networking in high performance computing clusters are described. The system uses a hybrid ultra-wideband orthogonal frequency division-multiplexing scheme. The transmitted signals are sparse pulse trains modulated by a frequency selected from a properly designed set of frequencies. The train itself consists of frequency modulated ultra-wide pulses. The system achieves good detection by integrating several pulses, and high throughput by transmitting frequencies in parallel. Unlike traditional orthogonal frequency division-multiplexing systems, a given tone is transmitted only during parts of the transmission interval.

### STATEMENT OF GOVERNMENT RIGHTS

This invention was made in part with a grant from the Government of the United States of America (award no. 9979443 from the National Science Foundation). The Government may have certain rights in the invention.

### FIELD

The present invention relates generally to wireless communications, and more particularly to high bit rate ultra-wideband orthogonal frequency division multiplexed (OFDM) communications.

### COPYRIGHT NOTICE/PERMISSION

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever. The following notice applies to the software and data as described below and in the drawings hereto: Copyright © 2002, Regents of the University of Minnesota, All Rights Reserved.

### BACKGROUND

Ultra-wideband (UWB) typically transmits ultra-low power radio signals with very short electrical pulses, often in the picosecond (1/1000th of a nanosecond) range, across many frequencies at once. UWB communication systems typically use signals with a fractional bandwidth that is larger than 25% of the center frequency, or more than 1.5 GHz. Several UWB communications schemes have been proposed. These systems typically use pulse-amplitude or pulse position modulation and different pulse generation methods, pulse rate and shape, center frequency and bandwidth. Most of these systems generate and radiate the impulse response of a wideband microwave antenna and use that response as their basic pulse shape. Some systems utilize careful baseband pulse shaping and RF modulation techniques to control the center frequency and bandwidth of the radiated pulses.

UWB communication systems offer several potential advantages. For example, the wide bandwidth of such systems generally makes them more robust to multipath interference. A direct application of the Shannon's channel capacity theorem to an additive white Gaussian noise channel shows that such systems also offer a potentially high bit rate transmission capability with capacity increasing almost linearly with power. Finally, the fine time resolution of UWB systems makes them good candidate for ranging applications. Indeed, much of the earlier work in UWB systems occurred in the radar field. Recognizing the potential benefits of UWB systems, the FCC has opened up the 3.1-10.6 GHz to indoor UWB transmission subject to power limitations.

Orthogonal frequency division multiplexing (OFDM) is a multi-carrier transmission technique that uses orthogonal subcarriers to transmit information within an available spectrum. Because the subcarriers may be orthogonal to one another, they may be spaced much more closely together within the available spectrum than, for example, the individual channels in a conventional frequency division multiplexing (FDM) system.

While UWB and OFDM each provide benefits for wireless communications, the data rates achieved by these systems has been inadequate for many purposes. For example, data rates of less than 100 Mb/s that have been reported so far by UWB systems and aggregate rates of less than 800 Mb/s for existing orthogonal frequency division-multiplexing OFDM schemes. As a result, there is a need in the art for the present invention.

### SUMMARY

The above-mentioned shortcomings, disadvantages and problems are addressed by the present invention, which will be understood by reading and studying the following specification.

The embodiments of the invention provide a novel multi-user communication scheme that relies on the modulation of a basic sparse train of pulses by a set of pre-determined, uniformly spaced frequencies. The train of pulses itself consists of carefully frequency modulated UWB pulses. The design of this train of pulses (or equivalently, the design of the modulation scheme used to produce the train from the basic pulse shape) is equivalent to the design of high-resolution pulses in radar system. Specifically, the ambiguity function of the train of pulses is designed to provide very fine time resolution and a frequency resolution that supports the transmission of several frequencies in parallel, while guaranteeing that the resulting signals are orthogonal (or nearly so) in the absence of multipath. Unlike traditional orthogonal frequency division-multiplexing systems, a given tone is transmitted only during parts of the transmission interval. Reliable communication results from integrating several pulses, and high throughput from transmitting frequencies in parallel.

In addition to the aspects and advantages of the present invention described in this summary, further aspects and advantages of the invention will become apparent by reference to the drawings and by reading the detailed description that follows.

### BRIEF DESCRIPTION OF THE DRAWINGS

FIG. 1 illustrates an envelop of ultra-wideband orthogonal frequency division multiplexed (UWB-OFDM) pulse train according to an embodiment of the invention;

FIG. 2 is a graph illustrating an upper bound on |X⁽²⁾(t,f)|/N as a function of N for Gaussian pulse s(t)=exp (−t²/T_{S}²)/{fourth root}\sqrt{π}T_{S}²), a pulse train p(t) with T=T_{C}, for various ratios T/T_{S}. according to various embodiments of the invention; and

FIG. 3 is a graph illustrating the performance of system in accordance to an embodiment of the invention in an indoor multipath environment with Trms=25 ns and Tspread=120 ns.

### DETAILED DESCRIPTION

In the following detailed description of exemplary embodiments of the invention, reference is made to the accompanying drawings which form a part hereof, and in which is shown by way of illustration specific exemplary embodiments in which the invention may be practiced. These embodiments are described in sufficient detail to enable those skilled in the art to practice the invention, and it is to be understood that other embodiments may be utilized and that logical, mechanical, electrical and other changes may be made without departing from the scope of the present invention.

In the Figures, the same reference number is used throughout to refer to an identical component which appears in multiple Figures. Signals and connections may be referred to by the same reference number or label, and the actual meaning will be clear from its use in the context of the description.

The following detailed description is, therefore, not to be taken in a limiting sense, and the scope of the present invention is defined only by the appended claims.

The systems and methods of the present invention include the design of a high bit rate, communication network suitable for high performance computing clusters. In some embodiments, the network is a short-range (10 m -20 m) network. Nodes in the network typically comprise processors, main and secondary memory. It is desirable that the nodes exchange data at bit rates higher than 0.8 Gb/s with short latencies. Typically the nodes operate in a stationary mode from fixed positions, but their positions may be changed infrequently to satisfy re-configuration needs. In some embodiments, a hybrid ultra-wideband (UWB) orthogonal frequency division-multiplexing (UWB-OFDM) scheme is used for the application.

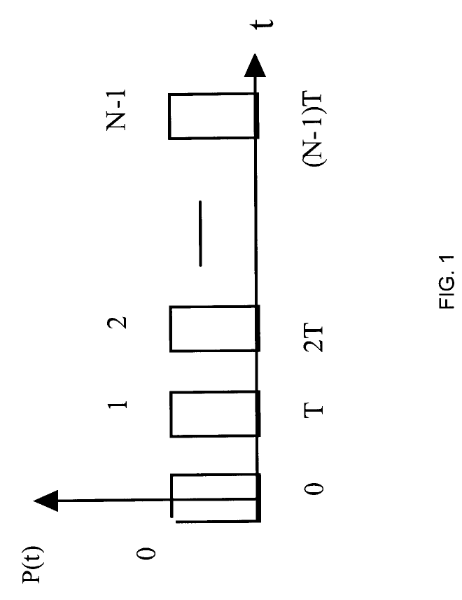

In some embodiments of the invention, systems and methods utilize the modulation of a basic sparse train of pulses by a set of pre-determined, uniformly spaced frequencies. The train of pulses itself consists of carefully frequency modulated UWB pulses (see FIG. 1). The design of this train of pulses (or equivalently, the design of the modulation scheme used to produce the train from the basic pulse shape) is equivalent to the design of high-resolution pulses in radar system. Specifically, the ambiguity function of the train of pulses is designed to provide very fine time resolution and a frequency resolution that supports the transmission of several frequencies in parallel, while guaranteeing that the resulting signals are orthogonal (or nearly so) in the absence of multipath. Unlike traditional orthogonal frequency division-multiplexing systems, a given tone is transmitted only during parts of the transmission interval. Reliable communication results from integrating several pulses, and high throughput from transmitting frequencies in parallel.

The specification is divided into multiple sections as follows. In Section I, the basic UWB-OFDM scheme is described. In Section II, design equations are provided. In Section III, the receiver structure and provide preliminary performance analysis of the proposed scheme in the presence of multipath is described. This analysis is applied in Section IV to a system that uses the recently approved FCC specifications and propagation and noise measurements and models that have been reported in the literature.

### I. DESCRIPTION OF UWB-OFDM

As noted above, the signal used in the various embodiments of the invention is a modulated sparse train p(t) of modulated short pulses s(t) uniformly spaced in time. Since s(t) is modulated, it need not have a zero DC value as in other UWB systems. For the purposes of this specification, it is assumed that s(t) is a general lowpass pulse, such as a rectangular or Gaussian pulse. For convenience, s(t) is normalized to have unit energy, i.e., ||s(t)||₂=1. It is also assumed for simplicity in describing the present invention that s(t) is centered around t=0, i.e., that the first moment of s²(t) is zero. Let T₀ be the root mean squared duration of the UWB pulse s(t), i.e., T₀ is the square root of the second moment of s²(t). Finally, let T be the repetition period of the pulse train p(t).

Referring to FIG. 1, we have

$$p ( t ) = {\sum }_{n = 0}^{N - 1} s ( t - nT ) {ⅇ}^{- j \frac{2 π c ( n ) t}{{T}_{c}}} , \qquad ( 1 )$$

where c(n) is a permutation of the integers {1, 2, . . . , N} that we will be discussed below. The transmitted signals fₖ(t), k=1, . . . , K, are given by

fₖ(t)=p(t)e^{-j2πkf}^{₀}^{t}, (2)

where f₀ is a fundamental frequency that is determined by p(t). The choice of f₀ will be discussed in detail below.

It is desirable to design p(t) such that the signals fₖ(t) are orthogonal or nearly so. Further, it is desirable to achieve a very fine time resolution to enable the receiver to distinguish between individual multipath components and combine them appropriately. This will mitigate the need for a complicated RAKE receiver.

Assume that in the presence of a (complex) white Gaussian noise process n(t) and the absence of multipath, the received signal r(t) at the detector due to fₖ(t) is

r(t)=a₀p(t−τ₀)e^{-j2πkf}^{₀}^{t}+n(t), (3)

where a₀ is a complex number that captures propagation effects. The performance of the optimal detector for deciding whether fₖ(t) was transmitted or not can be characterized by the ambiguity function Xₚ(τ,f) of p(t), where

$${X}_{p} ( τ , f ) = {\int }_{- ∞}^{∞} p ( t ) {p}^{*} ( t - τ ) {ⅇ}^{j 2 π f t} ⅆ t , \qquad ( 4 )$$

and p*(t) denotes the complex conjugate of p(t). In particular, the expected value of the sufficient statistic for deciding whether fₖ_{₀}(t−τ₀) is present or not, is Xₚ(0,0) if fₖ_{₀}(t−τ₀) is present, and 0 otherwise. Let hₖ_{₀}(t)=p*(−t−τ₀)e^{j2πk}^{₀}^{f}^{₀}^{t} be the matched filter used to determine whether fₖ_{₀}(t−τ₀) is present or not. The response of hₖ_{₀}(t) to the signal p(t−τ₁)e^{-j2πk}^{₁}^{f}^{₀}^{t} is Xₚ(τ₀−τ₁,(k₀−k₁)f₀).

It may be shown that Xₚ(τ, f) is given by

$$\begin{matrix}{X}_{p} ( τ , f ) = {\sum }_{n = 0}^{N - 1} {\sum }_{m = 0}^{N - 1} {ⅇ}^{- j 2 π \frac{m + n}{2} f T} {ⅇ}^{- j 2 π \frac{c ( m ) + c ( n )}{2 {T}_{c}} τ} \times \\ {X}_{s} ( τ + ( m - n ) T , f + ( c ( n ) - c ( m ) ) {T}_{c}^{- 1} ) \\ = {X}_{p}^{( 1 )} ( τ , f ) + {X}_{p}^{( 2 )} ( τ , f ) ,\end{matrix} \qquad ( 5 )$$

where

$$\begin{matrix}{X}_{p}^{( 1 )} ( τ , f ) = {X}_{s} ( τ , f ) {\sum }_{n = 0}^{N - 1} {ⅇ}^{- j 2 π nf T} {ⅇ}^{- j \frac{2 π c ( n ) τ}{{T}_{c}}} , & ( 6 ) \\ and & \\ \vert {X}_{p}^{( 2 )} ( τ , f ) \vert \leq {\sum }_{n = 0}^{N - 1} {\sum }_{{m = 0}_{m \neq n}}^{N - 1} \vert {X}_{s} ( τ + ( m - n ) T , f + ( c ( m ) - c ( n ) ) {T}_{c}^{- 1} ) \vert . & ( 7 )\end{matrix}$$

In the above equations, Xₛ(τ, f) is the ambiguity function of s(t). The magnitude of Xₚ⁽²⁾(τ,f) can be made small by proper choice of the sequence c(n). In one embodiment of the invention, c(n) is a Costas' sequence as noted in R. E. Blahut, “Theory of Remote Surveillance Algorithms,” in Radar and Sonar: Part I, R. E. Blahut, W. Miller, Jr. and C. H. Wilcox, Springer-Verlag, New York, 1991, which is hereby incorporated by reference herein. However, those of skill in the art will appreciate that other sequences could be used and are within the scope of the invention. In particular, if N+1 is a prime, then Xₚ⁽²⁾(τ, f) can be made small by selecting c(n)=αⁿ mod(N+1) where α is a primitive element of the integer arithmetic system modulo N+1. It may be shown that |Xₚ⁽²⁾(τ, f)|/N decays as 1/N.

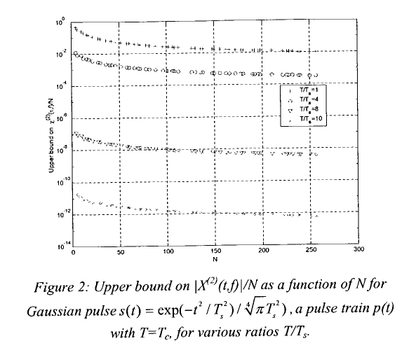

FIG. 2 provides an upper bound on |Xₚ⁽²⁾(τ, f)|/N for a train of Gaussian pulses s(t)=exp (−t²/T_{S}²)/{fourth root}\sqrt{π}T_{S}²) with T=T_{C} and various ratios T_{S}/T. When T_{S}/T≧8 for a Gaussian pulse, |Xₚ⁽²⁾(τ, f)|/N≦1.2×10⁻⁷. For the purposes simplifying the description of the invention, it will be assumed that c(n) is properly selected as indicated above and that the effect of Xₚ⁽²⁾(τ,f) will be neglected.

Equation (6) above provides a basis for selecting the fundamental modulating frequency f₀. Specifically, note that the inner product between f_{₁}(t−τ₁) and fₖ_{₂}(t−τ₁) is approximately equal to Xₚ⁽¹⁾(0,(k₁−k₂)f₀). It then follows from (6) that

$$\begin{matrix}{\int }_{- ∞}^{∞} p ( t - {τ}_{1} ) {p}^{*} ( t - {τ}_{1} ) {ⅇ}^{j 2 π ( {k}_{1} - {k}_{2} ) {f}_{0} t} ⅆ t \approx \frac{sin ( N π ( {k}_{1} - {k}_{2} ) {f}_{0} T )}{sin ( π ( {k}_{1} - {k}_{2} ) {f}_{0} T )} \times \\ {X}_{s} ( 0 , ( {k}_{1} - {k}_{2} ) {f}_{0} ) .\end{matrix} \qquad ( 8 )$$

Hence, if

$${f}_{0} = \frac{1}{NT} \qquad ( 9 )$$

then fₖ_{₁}(t−τ₁) and fₖ_{₂}(t−τ₁) will be approximately orthogonal provided that k₁−k₂ is an integer not equal to a multiple of N, or if k₁−k₂ is a multiple of N, that either |X_{S}(0,(k₁−k₂)f₀)|≈0 or the transmission of k₁f₀ and k₂f₀ are separated by an interval Δ such that |X_{S}(Δ,(k₁−k₂)f₀)|≈0. As discussed below, exact orthogonality can also be achieved by proper choice of s(t), N, T, T_{S} and f₀.

For the purposes of simplifying the description of the present invention, it will be assumed that equation (9) holds and that the integers k₁ defining the set of modulating frequencies is properly selected as discussed below to maximize the cardinality of that set subject to a given total bandwidth constraint.

Various embodiments of the invention employ differing methods for selecting the modulating frequencies kᵢf₀. In one embodiment of the invention, the modulation frequency is derived from pulse repetition, period and duration. A technique for ensuring orthogonality of fₖ(t) and fₘ(t) when k≠m is to use rectangular pulse s(t) of duration T_{S} and a frequency f₀ such that when the N pulses are reassembled with no gap in between subsequent pulses, one obtains one or more complete cycles of each frequency kf₀. This can be achieved by selecting N, T, T_{S} and f₀ as follows:

Nf₀T_{S}=1, (10)

and

T=T_{S}+mT₀, (11)

where m is an arbitrary integer. While this choice puts some restrictions on N, T, T_{S} and f₀, it can have a number of practical benefits. First, the resulting transmitters and receivers can simply be implemented using switches, oscillators and frequency dividers. Second, the number of orthogonal trains fₖ(t) that can be used by the system is now strictly limited by the available bandwidth. Third, the resulting pulse trains fₖ(t) are exactly orthogonal.

It should be noted that the principle outlined above can be generalized to other pulse shapes s(t). It is sufficient that s(t) be selected such that reassembling the N pulses, with no gap and potential overlap, leads one or more complete cycles of each frequency kf₀.

In an alternative embodiment of the invention, modulating frequencies are selected using a high duty cycle and/or properly selected UWB pulses s(t): The condition |X_{S}(0,(k₁−k₂)f₀)|≈0 can be achieved by selecting or designing s(t) properly or by choosing a duty cycle T₀/T that is close to one. For example, s(t) can be selected to be itself a train of pulses designed such that |X_{S}(0,m/T)|=0 for all integers m. Similarly, a rectangular pulse of duration T will have |X_{S}(0,m/T)|=0 for all integers m. Hence, for such a pulse and duty cycle, one can use all integers kᵢ. For a Gaussian pulse s(t)=exp (−t²/T_{S}²)/{fourth root}\sqrt{π}T_{S}²), |X_{S}(0,m/T)|<0.001 for T_{S}/T≧0.84.

In a further alternative embodiment of the invention, modulating frequencies as selected based on a sub-sampled set of harmonics. In these embodiments, a technique for achieving near orthogonality of the transmitted signals in the absence of multipath is to use a subset of all integers to define the modulating higher harmonics. In particular, if C is the smallest integer larger than one such that |X_{S}(0,C/T)|≈ε for an appropriately small ε, then one can select the integers k₁ to be of the form kᵢ=lCN+m, with l an integer and 0≦m≦N−1. As an example, for the Gaussian pulse mentioned above and with T_{S}/T=0.35, subsequent pulses s(t) in p(t) cross at a point where their amplitude is less than 1.7% of its peak value and X_{S}(0,2/T)<0.008. Hence, one could use C=2.

In a still further embodiment of the invention, modulating frequencies are selected based on time-staggered transmission of groups of harmonics: An effective solution is to transmit groups of N frequencies in intervals of length T with the start of a given interval separated from that of the immediately preceding one by a fixed time delay Δ so that |X_{S}(Δ,(k₁−k₂)f₀)|≈0. Specifically, observe that equation (6) implies that the inner product between fₖ_{₁}(t−τ₁) and fₖ_{₂}(t−τ₁−nT_{c}) is nearly zero for 1≦n≦N−1. Hence, near orthogonality of the transmitted pulse trains can be achieved by transmitting the 1^{st} N harmonics (0≦k₁≦N−1) at T₁, the 2^{nd} N harmonics (N≦kᵢ≦2N−1) starting at T₁+T_{c}, etc., with the k^{th} set (K<N) of N harmonics transmitted starting at T₁+kT_{c}. Many variations on this basic scheme are possible and within the scope of the invention. For example, if |X_{S}(0,C/T)|≈ε for an appropriately small ε, one can transmit all harmonics kf₀, where

k=lCN+m, 0≦m≦N−1,

in the same time slot.

In yet a further embodiment of the invention, modulating frequencies are selected through the use of different sequences c(n). In these embodiments, a different pulse train p(t) is used for each group of N frequencies k₁f₀. The different pulse trains are formed as in equation (1) with the sequence c(n) given by a cyclic rotation of the basic Costas sequence. In that case, |Xₚ⁽¹⁾(0,(k₁−k₂)f₀)|/N≦B/\sqrt{N} when (k₁−k₂)≧N for some constant B. Hence, fₖ_{₁}(t) and fₖ_{₂}(t) will be nearly orthogonal when N is large enough.

Several techniques for selecting modulating frequencies used by various embodiments of the invention have been described above. However, no embodiment of the invention is limited to those techniques previously discussed, other options are possible and within the scope of the invention.

An advantage of UWB signals is their finer multipath resolution capability. As seen from the above description and equation (6), the pulse train p(t) provides a frequency resolution on the order of T_{c}/N. Specifically,

$$\begin{matrix}{\int }_{- ∞}^{∞} p ( t - {τ}_{1} ) {p}^{*} ( t - {τ}_{2} ) ⅆ t \approx \frac{sin ( N π ( {τ}_{1} - {τ}_{2} ) / {T}_{c} )}{sin ( π ( {τ}_{1} - {τ}_{2} ) / {T}_{c} )} \times \\ {X}_{s} ( {τ}_{1} - {τ}_{2} , 0 ) .\end{matrix} \qquad ( 12 )$$

Therefore, p(t−τ₁) and p(t−τ₂) will be nearly orthogonal as long as |τ₁−τ₂|=m T_{c}/N, 0≦m≦N−1. In other words, system and methods of some embodiments of the invention can resolve multipath separated by m T_{c}/N seconds, 0≦m≦N−1. If m>N−1, then the ability of the system to unambiguously resolve multipath will depend on X_{S}(τ₁−τ₂,0). However, this ambiguity is not a concern for the design of communications link.

Because T_{c}/N is usually much smaller than T_{S}, UWB-OFDM receivers offer an even finer multipath resolution capability then other UWB systems. This opens up the possibility of using a whole slew of diversity techniques.

### II. DESIGN EQUATIONS

This section will provide design equations based on the discussion above. These design equations enable the selection of the parameters of the system for given a bit rate goal and system and operational constraints.

First, the following parameters are described:

Bs: Bandwidth of UWB pulse s(t)

Bp: Bandwidth of train of pulses p(t)

B_{T}: Total available system bandwidth

K: Index of highest modulating harmonic of f₀

By combining the discussion above with equations (1), (2), (8) and (12), one obtains

N=(Bₚ−Bₛ)T_{c}+1, (13)

K=(B_{T}−Bₚ)NT+1, (14)

$$Bit Rate \approx \frac{( {B}_{T} - {B}_{p} )}{β} b \text{/} s , \qquad ( 15 )$$

where β=1 if one selects N, T, T_{S} and f₀ according to equations (10)-(11), or uses the high-duty cycle, time-staggered or cyclic shift of Costas sequence modulation schemes in embodiments described above. In embodiments using the sub-sampled harmonic set modulation scheme described above, β=C. Equations (9)-(11) and (13)-(15) are the desired design equations.

### III DETECTOR STRUCTURE AND PERFORMANCE ANALYSIS

This section evaluates the performance of an embodiment of a UWB-OFDM On-Off or binary shift keying (BSK) system in a dense multipath channel. As those of skill in the art will appreciate, other modulation schemes can be supported and are within the scope of the invention. These other modulation schemes include binary phase shift keying (PSK), frequency shift keying (FSK) and quadrature amplitude modulation (QAM), to mention a few.

Some embodiments of the invention use a delay-tapped model for the transmission channel as described in J. R. Foerster, “The effects of multipath interference on the performance of UWB systems in an indoor wireless channel,” 53rd IEEE Vehicular Technology Conference (VTC 2001 Spring), vol. 2, pp. 1176-1180 vol.2, 2001, which is hereby incorporated by reference herein, and assume that the multipath is resolvable by p(t). The impulse response of the channel is modeled as:

$$h ( t ) = {\sum }_{l = 0}^{L - 1} {δ}_{l} {α}_{l} δ ( t - {lT}_{r} ) \qquad ( 16 )$$

where L is the number of resolvable paths and Tᵣ=T_{c}/N. Each random variable δ₁, takes the value 0 or 1 and indicates the presence of a multipath component at delay lTᵣ of complex amplitude α₁. Note that L depends on Tᵣ and Tᵣₘₛ the RMS delay spread of the channel. It is also assumed that independent Rayleigh fading on different multipath, i.e., the α₁'s are independent complex Gaussian processes with E[|α₁|²]=Ae^{-e1/L} for a given L. It should be noted that this implies that the received power of the Lth path is more than 30 dB below that of the first arrival. Finally, some embodiments use a Δ−K model to model multipath arrival times with parameters similar to those used in Foerster, i.e., Tᵣₘₛ=25 n sec, λ=⅔ and K=0.5.

The received signal is:

$$f ( t ) = 2 \sqrt{\frac{{E}_{b}}{N}} {\sum }_{k = 1}^{K} {b}_{k} {f}_{k} ( t ) , \begin{matrix} & & 0 \leq t \leq NT\end{matrix} \qquad ( 17 )$$

where fₖ(t) is defined in equation (4). The coefficients bₖ are equal to 0 or 1 and represent the transmitted bit in subcarrier k. Note that the normalization in equation (17) implies that E_{b} is the average received energy per bit independent of N. The received signal equals:

$$r ( t ) = {\sum }_{l = 0}^{L - 1} {δ}_{l} {α}_{l} f ( t - {lT}_{r} ) + n ( t ) \qquad ( 18 )$$

where n(t) is a zero-mean complex white Gaussian noise process of intensity N₀. The output of the match filter corresponding to subchannel m is equal to

$$\begin{matrix}y ( t ) = r ( t ) * {p}^{*} ( - t ) {ⅇ}^{- j 2 π {mf}_{0} t} \\ = 2 \sqrt{\frac{{E}_{b}}{N}} {\sum }_{l = 0}^{L - 1} {\sum }_{k = 1}^{K} {b}_{k} {δ}_{l} {α}_{l} {X}_{p} ( t - {lT}_{r} , ( m - k ) {f}_{0} ) + w ( t )\end{matrix} \qquad ( 19 )$$

where a phase factor has been absorbed into α₁. Equation (19) can be implemented efficiently using a single matched filter matched to s(t), followed by a realignment of the matched filter output and a discrete Fourier transform operation taken along the period index.

Now, recall that fₖ(t) is nearly orthogonal to fₘ(t), m≠k, and is also nearly orthogonal to its resolvable multipath components.

If the multipath is known and the receiver and transmitter are synchronized, one can sample y(t) at t=iTᵣ for i=0, . . . ,L−1:

$$\begin{matrix}{y}_{i} = y ( i {T}_{r} ) \\ = 2 \sqrt{\frac{{E}_{b}}{N}} {\sum }_{l = 0}^{L - 1} {\sum }_{k = 1}^{K} {δ}_{l} {α}_{l} {b}_{k} {X}_{p} ( ( i - l ) {T}_{r} , ( m - k ) {f}_{0} ) + {w}_{i} \\ ≃ 2 \sqrt{{E}_{b} N} {δ}_{i} {α}_{i} {b}_{m} + {v}_{i} + {w}_{i} , i = 0 , … , L - 1\end{matrix} \qquad ( 20 )$$

or in vector form:

\vec{y}=2\sqrt{E_{b}N}bₘ\vec{α}+\vec{v}+\vec{w}. (21)

In the equations above, the random variables wᵢ are independent zero mean complex Gaussian random variables with variance NN₀. The random variables v₁ capture the interference between fₘ(t) and the multipath components of fₖ(t), k≠m. Note that this interference can be minimized by properly selecting T_{c} and T. In particular, the random variables vᵢ are independent zero mean complex Gaussian random variables that are linear combinations of the variables α₁, l≠i, and are independent of the random variables wᵢ. It may be shown that the variance of each v₁ can be written in the following form.

δᵥ^{2≅NE}_{b}γᵥ. (22)

where γᵥ is a function of s(t), p(t) and K. Conditioned on ||\vec{α}||², the bit error rate (BER) of the optimal RAKE receiver corresponding to equation (21) is equal to:

$${P}_{b} ( e \vert \vec{α} ) = Q ( \sqrt{\frac{{E}_{b}}{{N}_{0} + {γ}_{v} {E}_{b}} {‖ \vec{α} ‖}^{2}} ) . \qquad ( 23 )$$

In some embodiments, the range ambiguity discussed above is used to substitute for equation (16) an equivalent model that has N terms. Estimating \vec{α} to construct an optimal detector based on channel information is then equivalent to estimating the values of an N×1 Gaussian random vector derived from of using traditional spectral estimation techniques.

In an indoor wireless environment, the number of resolvable paths is large and N may also be large. A RAKE receiver then leads to a complicated receiver structure. Since the embodiments of the invention typically provide relatively fine multipath resolution, implementing a RAKE receiver can be avoided and instead the output of matched filter can be sampled at its peaks. The decision metric in this case is

$${\sum }_{i = 0}^{( L - 1 )} ( {ⅇ}^{- α / L} / ( A {ⅇ}^{- α / L} + {N}_{0} + {δ}_{v}^{2} / N ) {\vert {y}_{i} \vert}^{2} ,$$

(e^{-c1/L}/(Ae^{-c1/L}+N₀+δᵥ²/N)|y₁|², and is approximately equal to ||\vec{y}||² when the signal-to-noise ratio is high enough for reliable reception,.

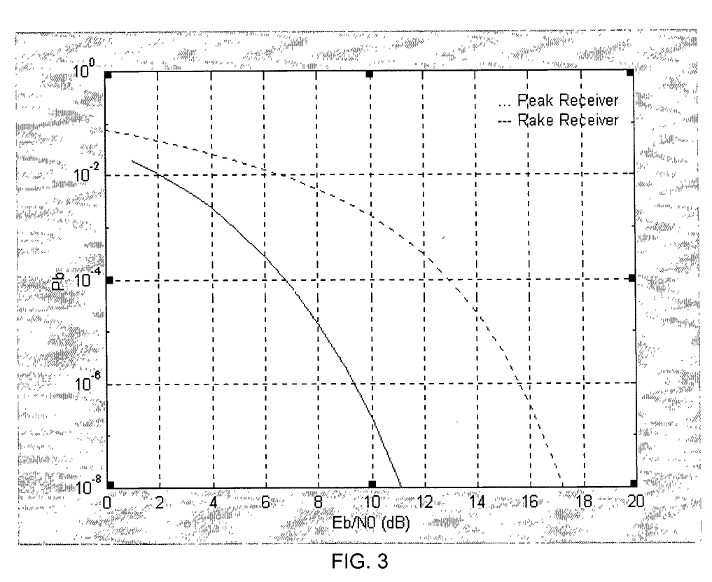

FIG. 3 shows the BER versus E_{b}/N₀ curves for the RAKE and peak detector receivers. FIG. 3 was derived using a simplified analysis that assumes that the random variables vᵢ are independent with γᵥ=10⁻².

### IV EXAMPLE SYSTEM DESIGN

To illustrate the capabilities of the embodiments of the invention, consider a system using Gaussian pulses with T_{S}=2 ns and set N=36, T=16 ns, Tc=14 ns and K=1153. According to equations (12)-(14) this system has Bₚ=5 GHz and a total FCC allocated bandwidth Bₜ=7 GHz. The total bit rate is equal to 2 Gb/s. From FIG. 3, we see that we need E_{b}/N₀=15 dB at the receiver to achieve a BER=10⁻⁵. Assuming a noise floor of −150 dBm/Hz, a link margin and a noise figure of 5 dB each and a path loss proportional to the square of the propagation distance, the system can accommodate up to 22 nodes simultaneously transmitting at 91 Mb/s at distances of up to 10 m with each remaining within the FCC regulations.

### Conclusion

Systems and methods for providing UWB-OFDM communications calls are disclosed. The systems and methods described provide advantages over previous systems. For example, the system is capable of achieving high bitrate rates on the order of 2 Gb/s over distances of 10 m or less under approved FCC specifications for systems in dense multipath indoor wireless environments. The systems and methods use a hybrid ultra-wideband orthogonal frequency division-multiplexing scheme. The transmitted signals are sparse pulse trains modulated by a frequency selected from a properly designed set of frequencies. The train itself consists of frequency modulated ultra-wide pulses. The system achieves good detection by integrating several pulses, and high throughput by transmitting several frequencies in parallel. Unlike traditional orthogonal frequency division-multiplexing systems, a given tone is transmitted only during parts of the transmission interval. Unlike traditional ultra-wideband communication systems, the systems and methods modulate each transmitted short pulse with a carefully selected carrier.

Although specific embodiments have been illustrated and described herein, it will be appreciated by those of ordinary skill in the art that any arrangement which is calculated to achieve the same purpose may be substituted for the specific embodiments shown. This application is intended to cover any adaptations or variations of the present invention.

The embodiments of the invention can be applied to a number of potential applications in several commercial and military fields, including:

wireless local area networks and wireless storage area networks

last mile distribution systems

geolocation and asset (RF tags) tracking

measurements of fluid levels, actuator positions, etc.

police and fire imaging equipment

sensor networks

covert handheld communication

The terminology used in this application is meant to include all of these environments. It is to be understood that the above description is intended to be illustrative, and not restrictive. Many other embodiments will be apparent to those of skill in the art upon reviewing the above description. Therefore, it is manifestly intended that this invention be limited only by the following claims and equivalents thereof.

We claim:

1. A method for data communication comprising:
generating a train of a plurality of pulses; and
modulating the train of pulses.

2. The method of claim 1, wherein modulating the train of pulses includes modulating the train of pulses over a plurality of modulating frequencies.

3. The method of claim 2, wherein the plurality of modulating frequencies are orthogonal.

4. The method of claim 3, wherein the pulses have a pulse repetition and pulse duration and further wherein the modulating frequencies are derived from the pulse repetition and pulse duration.

5. The method of claim 3, wherein the train of pulses has a duty cycle, and further wherein the duty cycle for the train of pulses is substantially close to 1.

6. The method of claim 3, wherein the modulating frequencies are selected according to a sub-sampled set of harmonics.

7. The method of claim 3, wherein the modulating frequencies comprise a plurality of groups of harmonics, and further comprising transmitting the modulating frequencies in a plurality of groups of harmonics such that each of the groups is separated by a predetermined time delay.

8. The method of claim 3, wherein the modulating frequencies comprise a plurality of groups, and further comprising generating a different pulse train for each of the plurality of groups.

9. The method of claim 1, wherein modulating the train of pulses includes binary shift keying.

10. The method of claim 1, wherein modulating the train of pulses includes binary phase shift keying.

11. The method of claim 1, wherein modulating the train of pulses includes frequency shift keying.

12. The method of claim 1, wherein modulating the train of pulses includes quadrature amplitude modulation.
